(19) United States
(12) Patent Application Publication
(10) Pub. No.: US 2026/0040627 A1
(43) Pub. Date: Feb. 5, 2026

(54) GALLIUM NITRIDE TRANSISTOR WITH DIELECTRIC CAP IN GATE STACK

(71) Applicant: Texas Instruments Incorporated, Dallas, TX (US)

(72) Inventors: Jackson Bauer, Rowlett, TX (US); Qhalid Fareed, Plano, TX (US); Karen Kirmse, Richardson, TX (US); Yoganand Saripalli, Allen, TX (US); James Teherani, Plano, TX (US)

(21) Appl. No.: 18/789,800

(22) Filed: Jul. 31, 2024

(51) Int. Cl. H01L 29/47; H01L 21/285; H01L 29/20; H01L 29/66; H01L 29/778

(52) U.S. Cl. CPC H10D 30/675; H01L 21/28581; H10D 30/015; H10D 30/475; H10D 30/6738; H10D 62/85; H10D 62/8503; H10D 64/64

(57) ABSTRACT

A transistor having a GaN stack on a substrate, an AlGaN barrier layer on the GaN stack, a gate stack including a p-GaN layer on the AlGaN barrier layer, a dielectric layer on a first portion of the p-GaN layer, and a gate electrode on the dielectric layer, and an AlGaN cap layer on a second portion of the p-GaN layer and laterally outward of a portion of the gate electrode. A method of fabricating a semiconductor device includes forming a dielectric layer on a patterned p-GaN layer and forming a gate electrode on the dielectric layer.

### BACKGROUND

Gallium nitride (GaN) transistors provide high gain and low noise operational advantages for high frequency switching circuitry, but power consumption, energy efficiency, and reliability can be adversely impacted by gate leakage. Off-state gate leakage increases stand-by power consumption, and on-state gate leakage can input increased gate noise to the device. Gate leakage can be caused by an insufficiently thick gate dielectric material, a poor insulator being used as a gate dielectric, or an insulator with small conduction or valence band offsets. Gate dielectric thickness variations can be caused by manufacturing variations such as dielectric layer deposition or dielectric layer etch rates. The transistor performance impact of such manufacturing variations may only be detectable at the end of a fabrication process.

### SUMMARY

In one aspect, semiconductor device includes a transistor having a dielectric layer on a first portion of a p-GaN layer, a gate electrode on the dielectric layer, and an AlGaN cap layer on a second portion of the p-GaN layer.

In another aspect, a transistor includes a GaN stack on a substrate, an AlGaN barrier layer on the GaN stack, a gate stack including a p-GaN layer on the AlGaN barrier layer, a dielectric layer on a first portion of the p-GaN layer, and a gate electrode on the dielectric layer, and an AlGaN cap layer on a second portion of the p-GaN layer and laterally outward of a portion of the gate electrode.

In a further aspect, a method of fabricating a semiconductor device includes forming a dielectric layer on a patterned p-GaN layer and forming a gate electrode on the dielectric layer.

### BRIEF DESCRIPTION OF THE DRAWINGS

FIG. 1 is a partial sectional side elevation view of a semiconductor device with a gallium nitride transistor having a high bandgap gate dielectric.

FIG. 2 is a partial sectional side elevation view of another semiconductor device with a gallium nitride transistor having a high bandgap gate dielectric.

FIG. 3 is a flow diagram of a method of fabricating a semiconductor device.

FIGS. 4-21 are partial sectional side elevation views of the semiconductor device of FIG. 1 undergoing fabrication processing according to the method of FIG. 3.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufactured electronic apparatus such as an integrated circuit or other semiconductor device. While such examples may be expected to provide various improvements, no particular result is a requirement of the present disclosure unless explicitly recited in a particular claim.

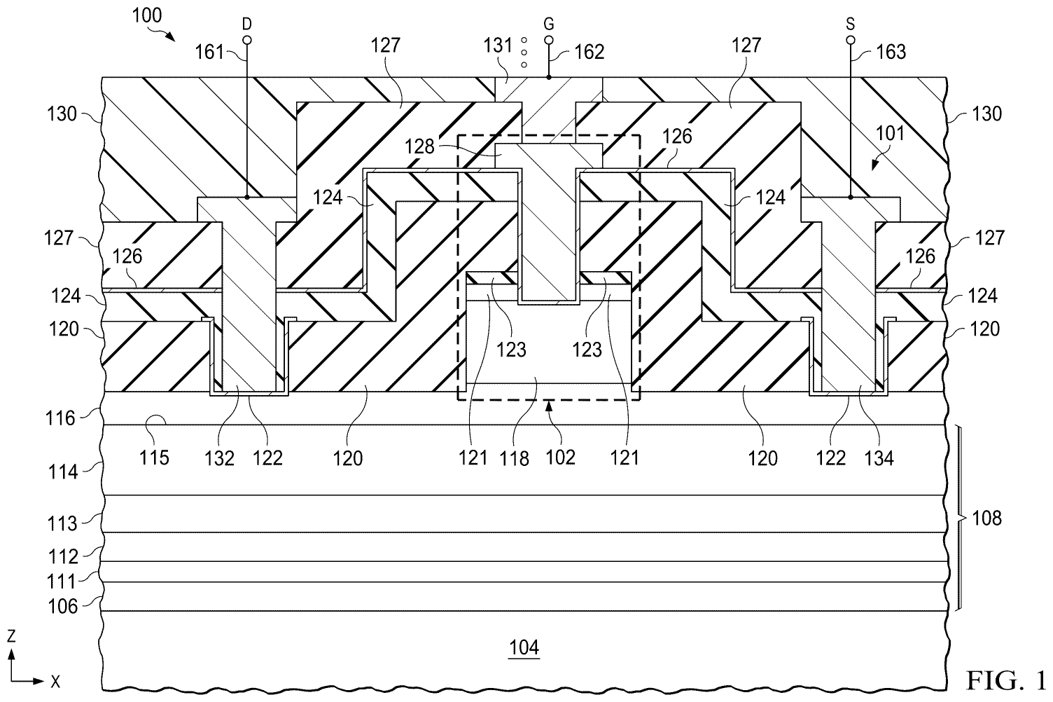

FIG. 1 shows a portion of a semiconductor die of a semiconductor device 100, such as a packaged integrated circuit product. The semiconductor device 100 includes an enhancement mode gallium nitride transistor 101 with a gate stack 102. The transistor 101 in one example is an enhancement mode high electron mobility transistor (HEMT) Gallium Nitride (GaN) transistor that includes a gate stack 102 with a high bandgap gate dielectric layer to mitigate gate leakage. The illustrated portion of the device 100 is initially fabricated in wafer form together with other semiconductor dies that are processed and then separated by a dicing process, before being separately packaged in finished integrated circuit products, also referred to as packaged semiconductor devices or electronic devices. The transistor 101 has a drain D, a source S and a gate G as schematically shown in FIG. 1.

The semiconductor device 100 can include other transistors on the same die or another die (not shown), for example, for half bridge or other integrated products high voltage switching power supply systems or other field applications. In certain example applications, the GaN transistor 101 can be operated as a high side switch coupled between a high voltage supply source and a switching node (not shown) or as a low side switch coupled between the switch node and a low voltage node, and the device may include an integrated inductor (not shown) in certain examples. The semiconductor device 100 is shown in an example three-dimensional space with a first direction X, a perpendicular (orthogonal) second direction Y (not shown, into the page in FIG. 1), and a third direction Z that is perpendicular (orthogonal) to the first and second directions X and Y. Structures or features along any two of these directions are orthogonal to one another.

In one example, the semiconductor device 100 includes a semiconductor substrate 104, such as silicon, and the substrate 104 can be electrically coupled to the source S. The semiconductor device 100 in one example has an epitaxially grown stack of layers including a buffer stack 108 formed on or above the semiconductor substrate 104 (e.g., directly on and contacting or having one or more intervening layers or structures). The individual layers of the stack structure are described herein as aluminum nitride, aluminum gallium nitride, gallium nitride, etc., and the individual layers can be of any suitable stoichiometric composition that is or includes the named constituent materials alone or in the further presence of small amounts of impurities, artifacts, or other materials, such as materials that may remain after individual processing steps associated with the manufacturer of semiconductor products.

The example stack includes an aluminum nitride (AlN) layer 106 over the substrate 104 (e.g., directly on and contacting or having one or more intervening layers or structures). In one example, the aluminum nitride layer 106 extends directly on and contacts the upper or top side of the substrate 104. In another example, other materials, such as impurities or artifacts or remnant materials from the fabrication processing may be present between the aluminum nitride layer 106 and the substrate 104. In one example, the aluminum nitride layer 106 has a thickness of approximately 300-600 nm.

The buffer stack 108 in one example is or includes a multilayer composition graded aluminum gallium nitride (AlGaN) buffer stack 108 that extends over the aluminum nitride layer 106 (e.g., directly on and contacting or having one or more intervening layers or structures). The buffer stack 108 in this example includes three layers that are or include aluminum gallium nitride. In other examples, a different number of two or more composition graded aluminum gallium nitride buffer stack layers can be used. In different examples, a different buffer stack arrangement can be used, such as single or dual superlattice buffer structures (not shown), a single layer or a non-composition graded AlGaN buffer stack 108, etc.

The example buffer stack 108 in FIG. 1 includes a first aluminum gallium nitride layer 111 over the aluminum nitride layer 106. In one example, the first aluminum gallium nitride layer 111 extends directly on and contacts an upper or top side of the aluminum nitride layer 106. In another example, other materials, such as impurities or artifacts or remnant materials from the fabrication processing may be present between the first aluminum gallium nitride layer 111 and the aluminum nitride layer 106.

The example composition graded AlGaN buffer stack 108 also includes a second aluminum gallium nitride layer 112 over the first aluminum gallium nitride layer 111 (e.g., directly on and contacting or having one or more intervening layers or structures). In one example, the second aluminum gallium nitride layer 112 extends directly on and contacts an upper or top side of the first aluminum gallium nitride layer 111. In another example, other materials, such as impurities or artifacts or remnant materials from the fabrication processing may be present between the second aluminum gallium nitride layer 112 and the first aluminum gallium nitride layer 111.

In the illustrated example, a third aluminum gallium nitride layer 113 extends over the second aluminum gallium nitride layer 112 (e.g., directly on and contacting or having one or more intervening layers or structures). In one example, the third aluminum gallium nitride layer 113 extends directly on and contacts an upper or top side of the second aluminum gallium nitride layer 112. In another example, other materials, such as impurities or artifacts or remnant materials from the fabrication processing may be present between the third aluminum gallium nitride layer 113 and the second aluminum gallium nitride layer 112.

In one example, the first aluminum gallium nitride sublayer 111 has a first aluminum concentration, the second aluminum gallium nitride sublayer 112 has a second aluminum concentration that is less than the first aluminum concentration, and the third aluminum gallium nitride sublayer 113 has a third aluminum concentration that is less than the second aluminum concentration. In one example, the first aluminum concentration is approximately 60-70%, the second aluminum concentration is approximately 40-50%, and the third aluminum concentration is approximately 20-30%. In one example, the first aluminum gallium nitride layer 111 has a thickness of approximately 300-600 nm, the second aluminum gallium nitride layer 112 has a thickness of approximately 1.4-1.8 μm, and the third aluminum gallium nitride layer 111 has a thickness of approximately 1.4-2.0 μm.

The buffer stack 108 further includes a gallium nitride layer 114 over the multilayer composition graded aluminum gallium nitride layers 111-113 (e.g., directly on and contacting or having one or more intervening layers or structures). In one example, the gallium nitride layer 114 has a thickness of approximately 0.5-2.0 μm. In this or another example, the gallium nitride layer 114 has a thickness of approximately 0.1-1.0 μm. In one implementation, the gallium nitride layer 114 includes carbon. In one example, the gallium nitride layer 114 extends directly on and contacts an upper or top side of the third aluminum gallium nitride layer 113. In another example, other materials, such as impurities or artifacts or remnant materials from the fabrication processing may be present between the gallium nitride layer 114 and the third aluminum gallium nitride layer 113.

The example semiconductor device 100 also includes a barrier layer 116 over the buffer structure (e.g., directly on and contacting or having one or more intervening layers or structures). The barrier layer 116 in one example is or includes aluminum gallium nitride of any suitable stoichiometry. In one example, the barrier layer 116 extends directly on and contacts an upper or top side of the gallium nitride layer 114 at an interface 115 between the top side of the gallium nitride layer 114 and the bottom side of the barrier layer 116. In another example, other materials, such as impurities or artifacts or remnant materials from the fabrication processing may be present between the barrier layer 116 and the gallium nitride layer 114. The barrier layer 116 has a thickness, for example, from a few tens of nm to a few μm, such as approximately 20 nm to 5 μm. In this or another example, the barrier layer 116 is or includes aluminum gallium nitride (AlGaN), aluminum nitride (AlN), indium aluminum nitride (InAlN), or indium aluminum gallium nitride (InAlGaN) of any suitable stoichiometry.

The gate stack 102 extends on a portion of the aluminum gallium nitride barrier layer 116 (e.g., directly on and contacting or having one or more intervening layers or structures). In one example, the patterned gate stack 102 includes a doped upper gallium nitride layer 118, also referred to as a p-GaN layer 118 that includes p-type dopants. In one example, the p-GaN layer 118 is on the portion of the AlGaN barrier layer 116 (e.g., directly on and contacting or having one or more intervening layers or structures). In one example, the AlGaN barrier layer 116 is on the GaN stack 108 (e.g., directly on and contacting or having one or more intervening layers or structures).

A dielectric, such as a silicon nitride (SiN) layer 120 (also referred to as a first silicon nitride layer) extends over a portion of the aluminum gallium nitride barrier layer 116 (e.g., directly on and contacting or having one or more intervening layers or structures) and has s thickness of approximately 1650 Å (0.1650 μm). The first silicon nitride (SiN) layer 120 in one example is formed by a low pressure chemical vapor deposition (LPCVD) process. In one example, the first silicon nitride layer 120 extends along lateral sidewalls of the patterned gate stack 102 and over a portion of a top side of the patterned gate stack 102. The first silicon nitride layer 120 extends on the AlGaN barrier layer 116 and has an opening spaced apart from the p-GaN layer 118 for the drain D (e.g., drain opening) and another opening spaced apart from the p-GaN layer 118 for the source S (e.g., source opening).

The gate stack 102 in one example includes an AlGaN cap layer 121 and a dielectric layer 126 on respective portions of the p-GaN layer 118 (e.g., directly on and contacting or having one or more intervening layers or structures).

Conductive metal source/drain contacts 122 extend at least partially along sidewalls of the openings of the first silicon nitride layer 120 and on respective portions of the top of the aluminum gallium nitride barrier layer 116 (e.g., directly on and contacting or having one or more intervening layers or structures). In one example, the source/drain contacts 122 are or include one or more of titanium (Ti), aluminum, and/or copper, such as a titanium layer with a thickness of approximately 400 Å (0.04 μm), and a layer of aluminum copper (AlCu) with a thickness of approximately 1000 Å (0.1 μm).

The drain contact 122 extends on a portion of the AlGaN barrier layer 116 in the drain opening of the first silicon nitride layer 120 and is spaced apart from the p-GaN layer 118. The drain contact 122 has a sidewall portion that extends on a sidewall of the drain opening in the first silicon nitride layer 120. Similarly, the source contact 122 extends on a portion of the AlGaN barrier layer 116 in the source opening of the first silicon nitride layer 120 and is spaced apart from the p-GaN layer 118. The source contact 122 has a sidewall portion that extends on a sidewall of the source opening in the first silicon nitride layer 120.

A portion of a second silicon nitride layer 124 extends between the sidewall portion of the drain contact 122 and a drain terminal 132. Another portion of the second silicon nitride layer 124 extends between the sidewall portion of the source contact 122 and a source terminal 134. The second silicon nitride layer 124 extends over further portions of the first silicon nitride layer 120 and the patterned gate stack 102 and the respective source and drain (e.g., directly on and contacting or having one or more intervening layers or structures). The second silicon nitride layer 124 in one example is formed by a plasma enhanced chemical vapor deposition (PECVD) process.

In one example, the patterned gate stack 102 further includes another silicon nitride layer 123 on the AlGaN cap layer 121 (e.g., directly on and contacting or having one or more intervening layers or structures). The silicon nitride layer 123 in one example is formed by a low pressure chemical vapor deposition process. In one example, the silicon nitride layer 123 has a thickness of approximately 100 Å (e.g., 0.01 μm). In another example, the silicon nitride layer 123 can be omitted.

A dielectric layer 126 extends on a first portion of the p-GaN layer 118 (e.g., directly on and contacting or having one or more intervening layers or structures), and the AlGaN cap layer 121 extends on a second portion of the p-GaN layer 118 (e.g., directly on and contacting or having one or more intervening layers or structures). A gate electrode 128 extends on the dielectric layer 126 (e.g., directly on and contacting or having one or more intervening layers or structures). In one or more examples, the gate electrode 128 can be or include one or more of AlCu, TiW, and TiN. In one or more examples, the AlGaN cap layer 121 can be laterally outward of a portion of the gate electrode 128. In one or more examples, a further gate electrode 131 extends at least partially on a top side of the gate electrode 128 (e.g., directly on and contacting or having one or more intervening layers or structures). The further gate electrode 131 can be any conductive metal or combinations of conductive metals.

In one or more examples, the dielectric layer 126 includes one or more of Al₂O₃, SiO₂, HfO₂, ZrO₂, Ta₂O₅, TiO₂, La₂O₃, BaO, Sc₂O₃, Y₂O₃, Lu₂O₃, Nb₂O₅, AlN, ZrN, HfN, and Si₃N₄. In these or another example, the dielectric layer 126 can include one or more of a composite film and a multilayer film stack. In these or another example, the dielectric layer 126 can include one or more of a HfₓZr₁₋ₓO₂ composite film, an AlN/Al₂O₃ film stack, and an SiO₂/HfO₂ film stack. In these or another example, the dielectric layer 126 can have a thickness of approximately 20 Å or more and approximately 150 Å or less. In these or another example, the dielectric layer 126 can include a material with a bandgap greater than 5 eV.

In the above or other examples, the dielectric layer 126 can extend along a bottom of the gate electrode 128 and along a portion of a lateral side of the gate electrode 128. In these or another example, the dielectric layer 126 can continuously extend over a drain access region between the gate stack 102 and the drain contact 132. In these or another example, the dielectric layer 126 can continuously extend from the gate stack 102 to the drain contact 132, and the dielectric layer 126 can directly contact the drain contact 132. In these or another example, the dielectric layer 126 can continuously extend over a source access region between the gate stack 102 and the source contact 134. In these or another example, the dielectric layer 126 can continuously extend from the gate stack 102 to the source contact 134, and the dielectric layer 126 can directly contact the source contact 134.

The semiconductor device 100 in the above or other examples can include a further silicon nitride layer 127 on the dielectric layer 126, with openings for the drain and source contacts 132 and 134, as well as an opening for the further gate electrode 131. The semiconductor device 100 in one example can include a pre-metal dielectric (PMD) layer 130, which can be any suitable dielectric, such as silicon dioxide (SiO₂), and can include a single or multilevel metallization structure (not shown) above the PMD layer 130 with further interlayer or interlevel dielectric (ILD) layers and conductive traces and/or vias (not shown). The metallization structure in certain examples can provide electrical interconnections by conductive features (not shown) for a drain terminal 161, a gate terminal 162, and a source terminal 163 of the transistor 101, for example, to provide interconnections to other components of the semiconductor device 100 and/or to provide external connections to one or more terminals of the transistor 101.

The transistor 101 in one example includes the GaN stack 108 on the substrate 104, the aluminum gallium nitride barrier layer 116 on the GaN stack 108, the gate stack 102 including the p-GaN layer 118 on the aluminum gallium nitride barrier layer 116, the dielectric layer 126 on the first portion of the p-GaN layer 118, the gate electrode 128 on the dielectric layer 126, and the aluminum gallium nitride cap layer 121 on the second portion of the p-GaN layer 118 and laterally outward of a portion of the gate electrode 128.

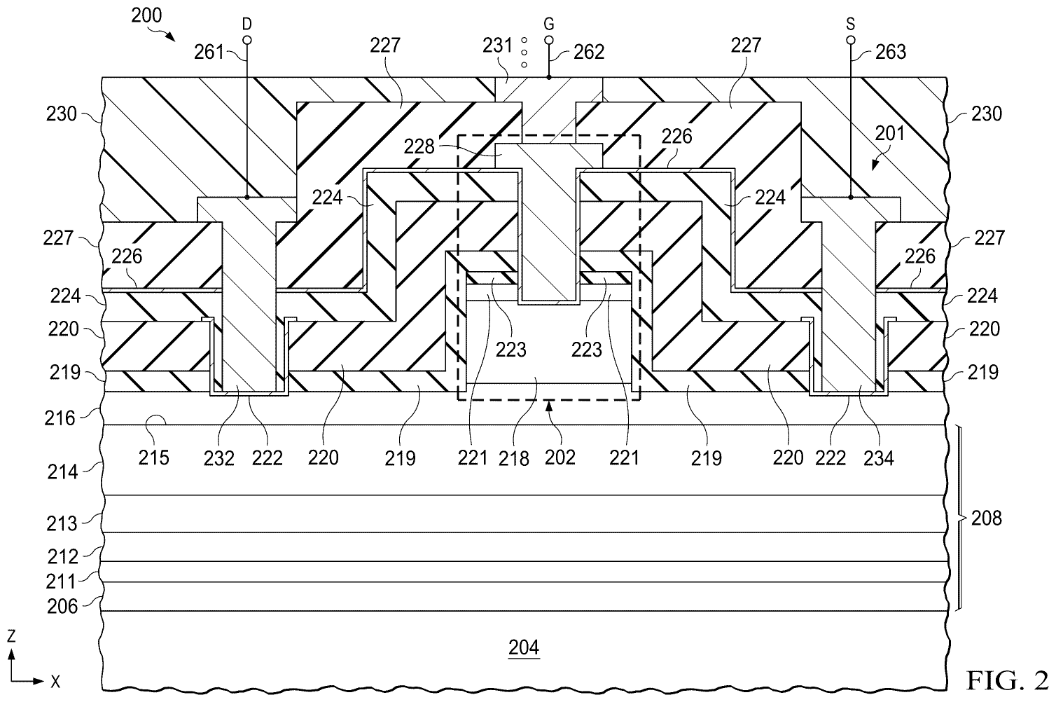

FIG. 2 shows another semiconductor device 200 with a gallium nitride transistor 201 having a high bandgap gate dielectric 219. The semiconductor device 200 in one example includes structures and/or features 201, 202, 204, 206, 208, 211-216, 220-224, 226-228, 230-232, 234, and 261-263 generally corresponding to the respective structures and/or features 101, 102, 104, 106, 108, 111-116, 120-124, 126-128, 130-132, 134, and 161-163 as described above in connection with FIG. 1 unless differently described below. The semiconductor device 200 provides a silicon nitride dielectric or other high bandgap dielectric layer 219. The silicon nitride layer 219 in one example extends on the AlGaN barrier layer 216 (e.g., directly on and contacting or having one or more intervening layers or structures). In this or another example, the silicon nitride dielectric 219 can extend on a side of the patterned gate structure, including along sidewalls of the p-GaN layer 218, on a side of the AlGaN cap layer 221, and on a sidewall and top side of the silicon nitride layer 223 (e.g., directly on and contacting or having one or more intervening layers or structures). In one example, the silicon nitride layer 219 has a thickness of approximately 50 to 150 Å (0.005 to 0.015 μm).

The semiconductor devices 100 and 200 and the respective transistors 101 and 201 of FIGS. 1 and 2 and alternate implementations thereof can advantageously facilitate high transistor gain and low noise operation, for example, in high frequency switching circuitry or other applications while mitigating gate leakage and excessive power consumption to provide good energy efficiency and/or reliability. The described examples can help ensure sufficient gate dielectric material thickness and suitable gate dielectric material consistency while mitigating gate dielectric thickness variations. In certain examples, the dielectric layer 126, 226 is formed to a controlled thickness independent of the deposition and subsequent processing of the aluminum gallium nitride cap layer 121, 221 and the operation of the dielectric layer 126, 226 is a gate dielectric of the transistor 101, 201 is not affected by variations in the deposition and/or etch processes performed with respect to the aluminum gallium nitride cap layer 121, 221.

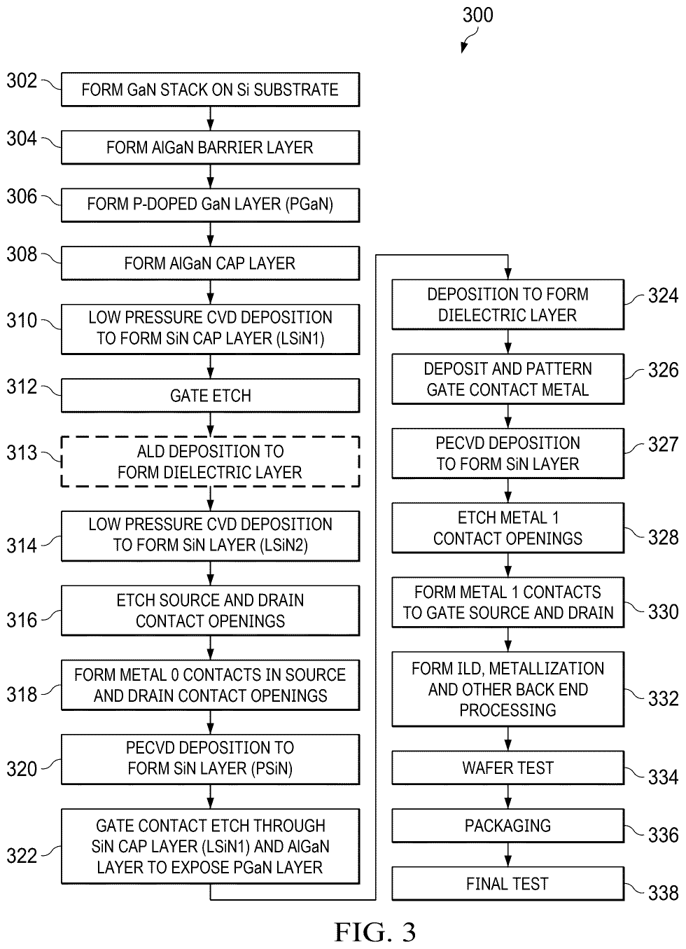

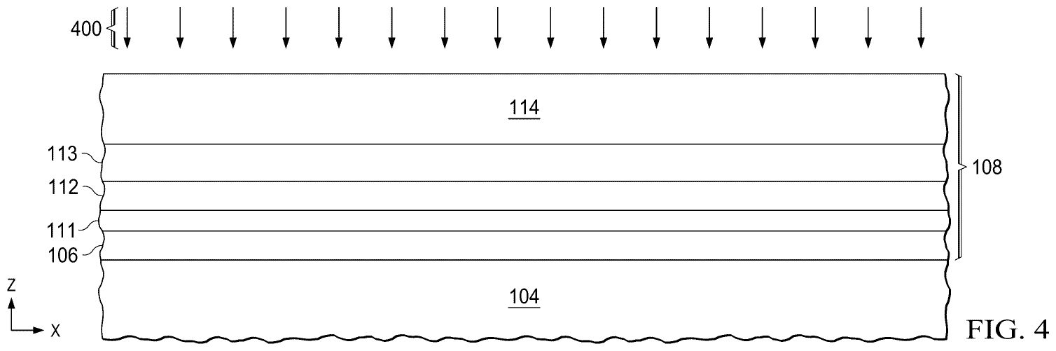

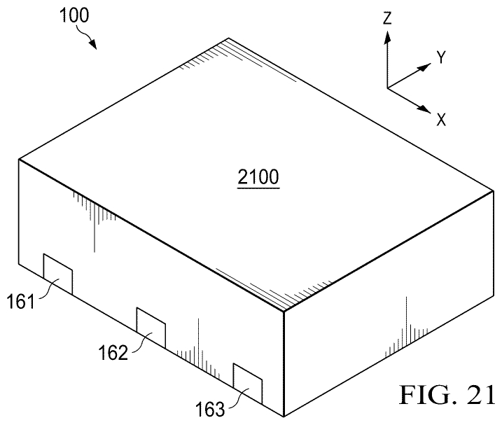

Referring now to FIGS. 3-21, FIG. 3 shows an example method 300 of making a semiconductor device according to a further aspect, FIGS. 4-20 show partial side views of the semiconductor device 100 of FIG. 1 undergoing fabrication processing according to the method of 300, and FIG. 21 shows a perspective view of the finished packaged semiconductor device 100. The method 300 begins with a starting substrate, such as a silicon wafer, an SOI wafer, etc. Similar processing can be used to fabricate one or more of the semiconductor device example 200 described above in connection with FIG. 2.

Rather than forming the gate dielectric at the beginning of the process, the example method 300 avoids exposing the dielectric layer 126, 226 to other processing earlier in the fabrication sequence, which other processing could otherwise expose the gate dielectric material to damage and to cause final thickness variations that can adversely affect transistor performance. Described examples of the method 300 can advantageously use the existing aluminum gallium nitride cap (e.g., layer 121, 221 above) to protect the gate structure (e.g., p-GaN layer 118, 218) during subsequent processing steps, and then the aluminum gallium nitride cap layer 121, 221 can be replaced with a superior dielectric (e.g., dielectric layer 126, 226) with more precisely controlled thickness and with a larger bandgap for reduced leakage to enhance manufacturability and/or improve device performance. The example method 300 in one implementation includes removal of a portion of the aluminum gallium nitride cap layer 121, 221 and subsequent deposition of the gate dielectric layer 126, 226.

The method 300 in one example begins at 302 in FIG. 3 with an epitaxial deposition process or multiple epitaxial deposition processes, including forming the buffer structure 108 with the aluminum nitride (AlN) layer 106 and the and layers 111-114 shown above in FIG. 1. FIG. 4 shows one example, in which an epitaxial deposition process or multiple epitaxial deposition processes 400 is/are performed that form the buffer structure 108 with the aluminum nitride (AlN) layer 106 and the layers 111-114 in FIG. 1. In one example, the aluminum nitride layer 106 is deposited over an upper surface of a silicon substrate 104 using an epitaxial deposition process, for example at a temperature of approximately 1000-1150° C. to a thickness of approximately 300-600 nm.

The method 300 continues with buffer formation, including forming the multilayer composition graded aluminum gallium nitride stack over the aluminum nitride layer 106. The multilayer composition graded aluminum gallium nitride stack formation at 302 in one example includes performing a first epitaxial deposition process that forms a first aluminum gallium nitride sublayer 111 over the aluminum nitride layer 106, for example, with an aluminum content of approximately 60-70% to a thickness of approximately 300-600 nm at a process temperature of approximately 900-1100° C. In one implementation, moreover, the process uses ethane, hexane or other extrinsic carbon source gas to form the first aluminum gallium nitride sublayer 111 with a carbon concentration of approximately 1E17-1E18 atoms/cm³.

The method 300 continues at 302 in one example with performing a second epitaxial deposition process that forms the second aluminum gallium nitride sublayer 112 over the first aluminum gallium nitride sublayer 111, for example, with an aluminum content of approximately 40-50% to a thickness of approximately 1.4-1.8 μm using a process temperature of approximately 200-1100° C. using ethane, hexane or other extrinsic carbon source gas to form the second aluminum gallium nitride sublayer 112 with a carbon concentration of approximately 1E17-1E19 atoms/cm³.

The method 300 continues at 302 in one example with performing a third epitaxial deposition process that forms the third aluminum gallium nitride sublayer 113 over the second aluminum gallium nitride sublayer 112, for example, with an aluminum content of approximately 20-30% to a thickness of approximately 1.4-2.0 μm using a process temperature of approximately 1000-1100° C. using ethane, hexane or other extrinsic carbon source gas to form the third aluminum gallium nitride sublayer 113 with a carbon concentration of approximately 1E17-1E19 atoms/cm³.

The method 300 in one example continues at 302 with performing an epitaxial deposition process that deposits a gallium nitride layer 114 over the top side of the third gallium nitride sublayer 113, for example, to a thickness of approximately 0.5-1.0 μm at a process temperature of approximately 900-1050° C. using hexane or other extrinsic carbon gas to provide the gallium nitride layer 114 with a carbon concentration of approximately 1E18-1E20 atoms/cm³.

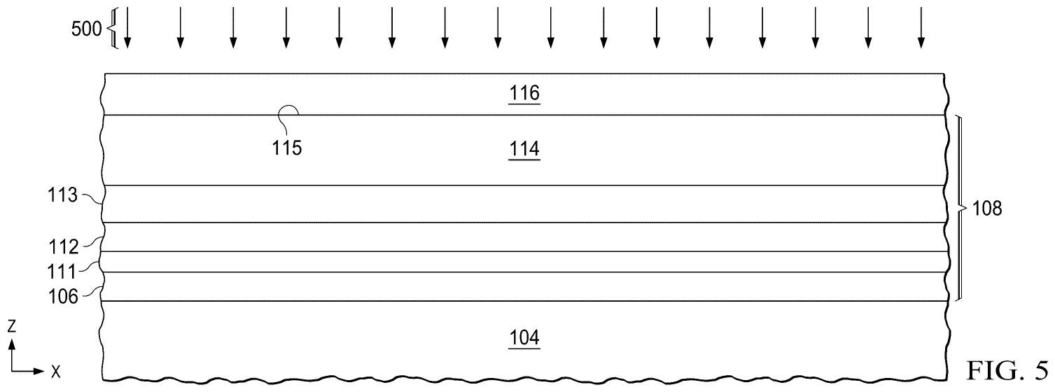

At 304 in FIG. 3, the method 300 continues with forming an aluminum gallium nitride barrier layer 116 on the buffer structure 108. FIG. 5 shows one example, in which an epitaxial deposition process 500 is performed that deposits the aluminum gallium nitride barrier layer 116 on the top side of the gallium nitride layer 114 to a thickness of from a few tens of nm to a few μm, such as approximately 20 nm to 5 μm.

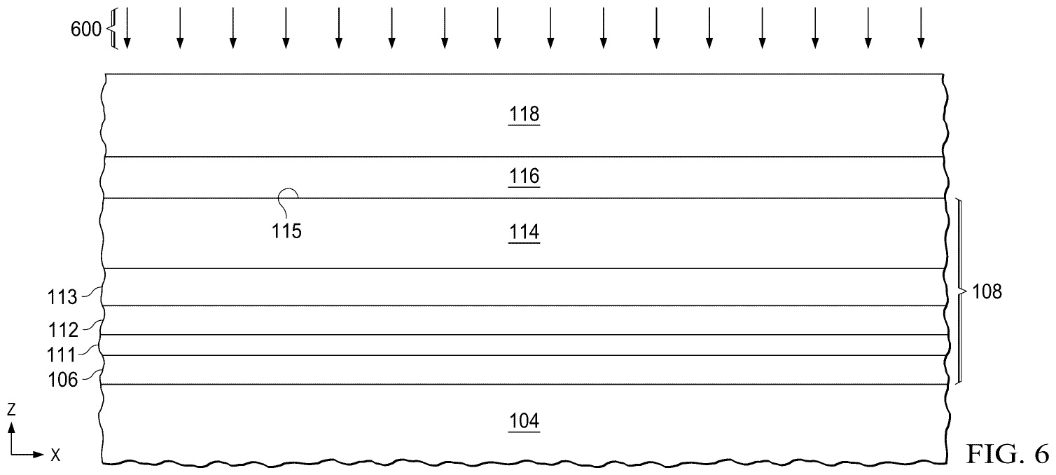

The method 300 continues at 306 in FIG. 3 with forming the p-GaN layer 118 over (e.g., directly on) the top side of the barrier layer 116. FIG. 6 shows one example, in which an epitaxial deposition process 600 is performed that deposits the p-GaN layer 118 on the barrier layer 116 to a thickness of approximately 0.1-1.0 μm at a process temperature of approximately 950-1050° C., with intrinsic carbon doping to a concentration of approximately 1E15-1E17 atoms/cm³.

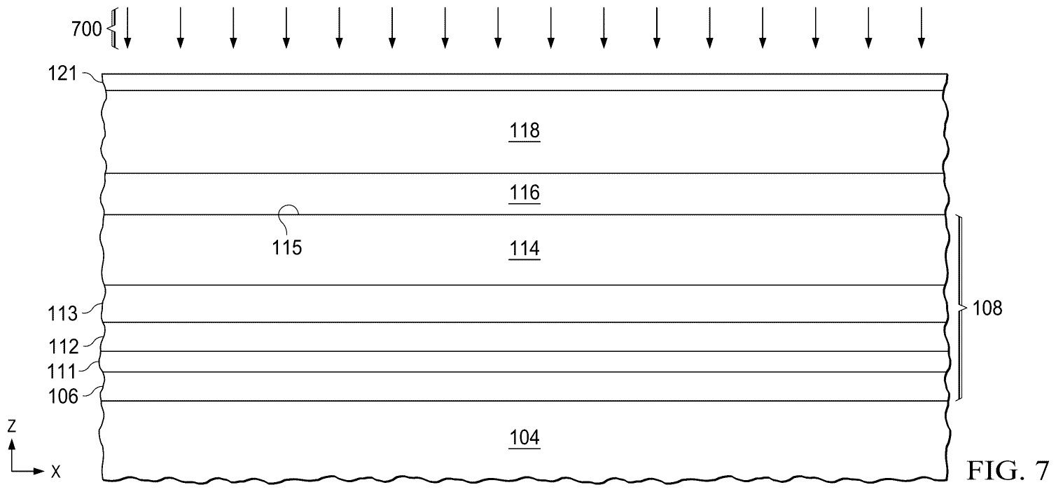

The method 300 continues at 308 in FIG. 3 with forming the aluminum gallium nitride cap layer 121. FIG. 7 shows one example, in which an epitaxial deposition process 700 is performed that deposits the aluminum gallium nitride cap layer 121 on (e.g., directly on) the p-GaN layer 118 to a thickness of approximately 4 nm.

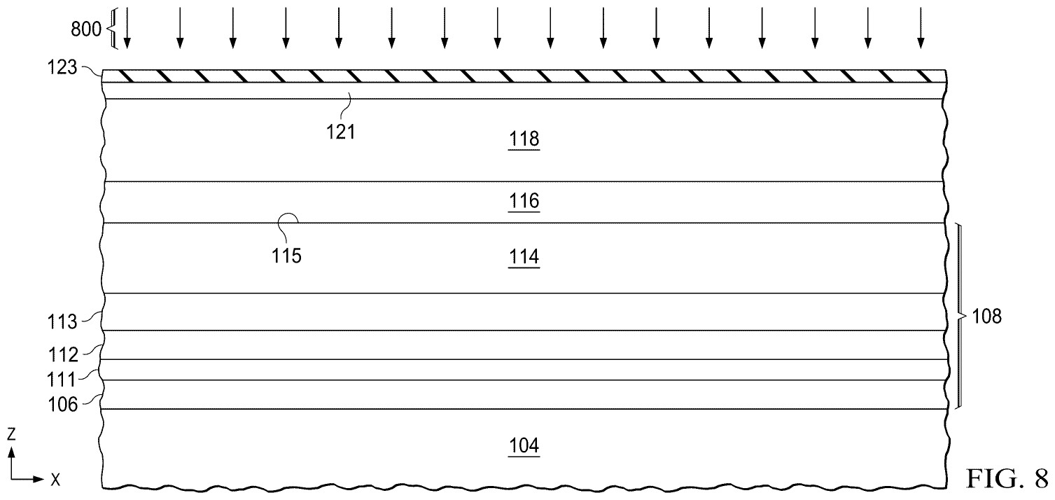

At 310 in FIG. 3, the method 300 continues with forming the silicon nitride layer 123 over the top side of the on the aluminum gallium nitride cap layer 121. FIG. 8 shows one example, in which a low-pressure CVD (LPCVD) deposition process 800 is performed that deposits the silicon nitride layer 123 (e.g., LSiN1) over (e.g., directly on) the top side of the aluminum gallium nitride cap layer 121 to a thickness of approximately 100 Å (0.01 μm).

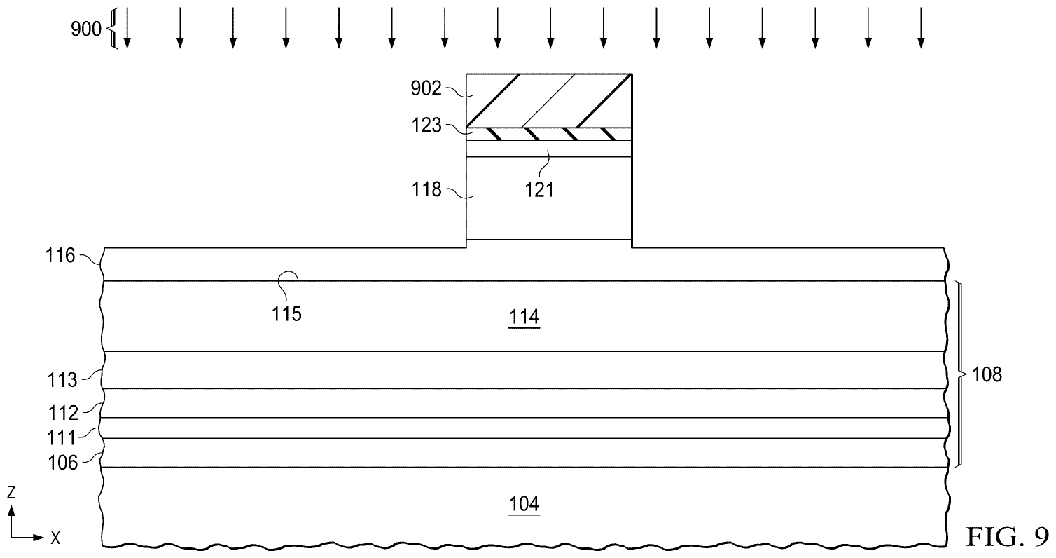

The method 300 continues at 312 with patterning the gate stack. FIG. 9 shows one example, in which an etch process 900 is performed using an etch mask 902 that covers the prospective portions of the patterned gate stack 102 described above. The etch process 900 etches through exposed portions of the layers 123, 121 and 118 and stops in the aluminum gallium nitride barrier layer 116. In one example, the etch mask 902 is used in a first patterning step to selectively remove portions of the silicon nitride layer 123, and then the silicon nitride layer 123 acts as an etch mask for removing exposed portions of the layers 121 and 118, stopping in the aluminum gallium nitride barrier layer 116. In this example, the patterned portion of the silicon nitride layer 123 can remain after the etch process 900. In one example, an isolation implant can be performed after the gate etch process 900 (e.g., immediately after 312 in FIG. 3)—e.g., to electrically isolate the GaN transistor 101 (or the gate stack 102). In one implementation, the isolation implant includes a 120 keV, 5e14 atoms/cm² dose of Ar+ that destroys the two dimensional electron gas (2DEG) in implanted regions through physical damage to the GaN structure.

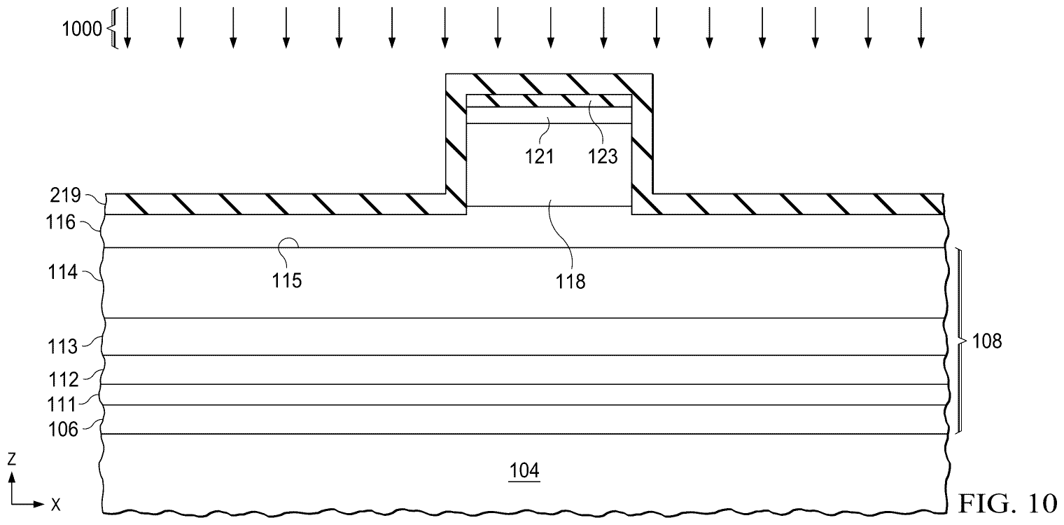

The method 300 in one example continues at 313 in FIG. 3 with formation of the further dielectric layer 219, for example, to form the above-described semiconductor device 200 of FIG. 2. FIG. 10 shows one example, in which a deposition process 1000 is performed that forms a silicon nitride dielectric layer 219 over (e.g., directly on) the patterned gate stack layers 118, 121, and 123, and on the exposed (e.g., etched) top surfaces of the aluminum gallium nitride barrier layer 116 to a thickness of approximately 50 to 150 Å (0.005 to 0.015 μm). In another implementation, the dielectric layer formation at 313 can be omitted, for example, to form the semiconductor device 100 as described above in connection with FIG. 1.

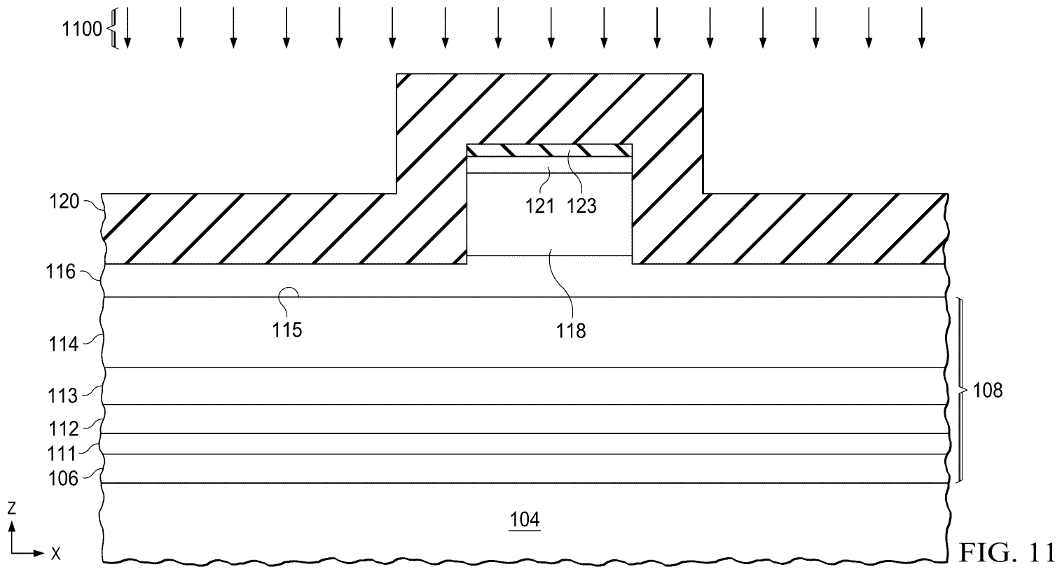

At 314 in FIG. 3, the method 300 includes forming another silicon nitride layer. FIG. 11 shows one example, in which a low-pressure CVD (LPCVD) deposition process 1100 is performed that deposits the silicon nitride layer 120 (e.g., LSiN2) over (e.g., directly on) the top side of the patterned gate stack layers 118, 121 and 123 and the exposed (e.g., etched) top surfaces of the aluminum gallium nitride barrier layer 116 to a thickness of approximately 1650 Å (0.165 μm).

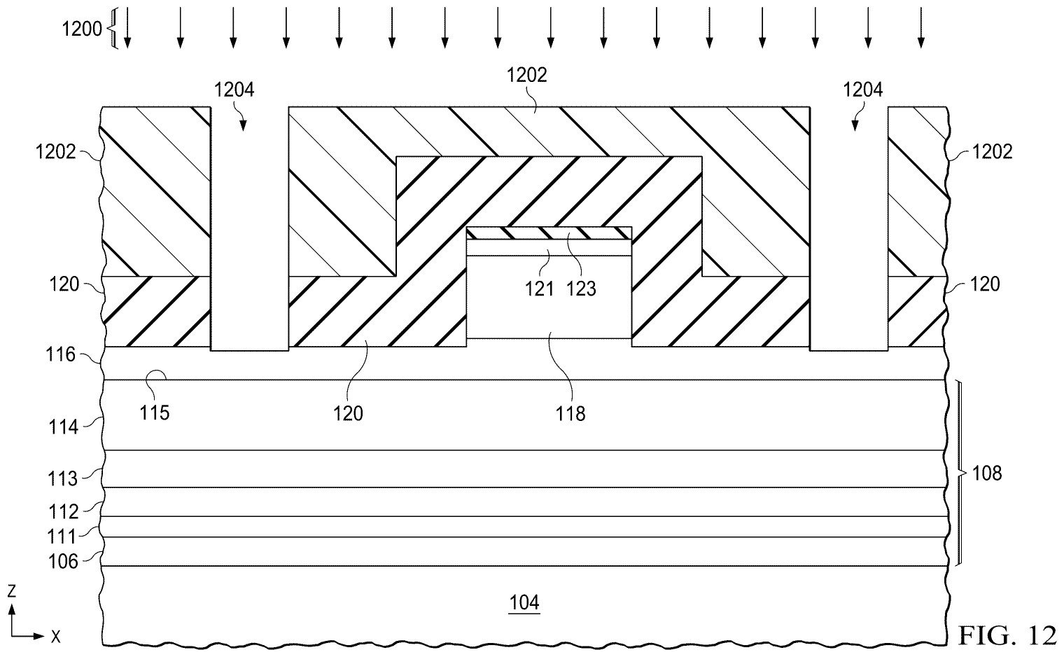

The method 300 in one example continues at 316 in FIG. 3 with etching source and drain contact openings. FIG. 12 shows one example, in which an etch process 1200 is performed using an etch mask 1202 to create source and drain contact openings 1204 that extend through the silicon nitride layer 120 to expose a portion of the aluminum gallium nitride barrier layer 116. In implementations using the further dielectric layer 219 (e.g., formed at 313 in FIG. 3), the etch process 1200 etches through the further dielectric layer 219 and through the silicon nitride layer 120 to expose an etched surface of the aluminum gallium nitride barrier layer 116.

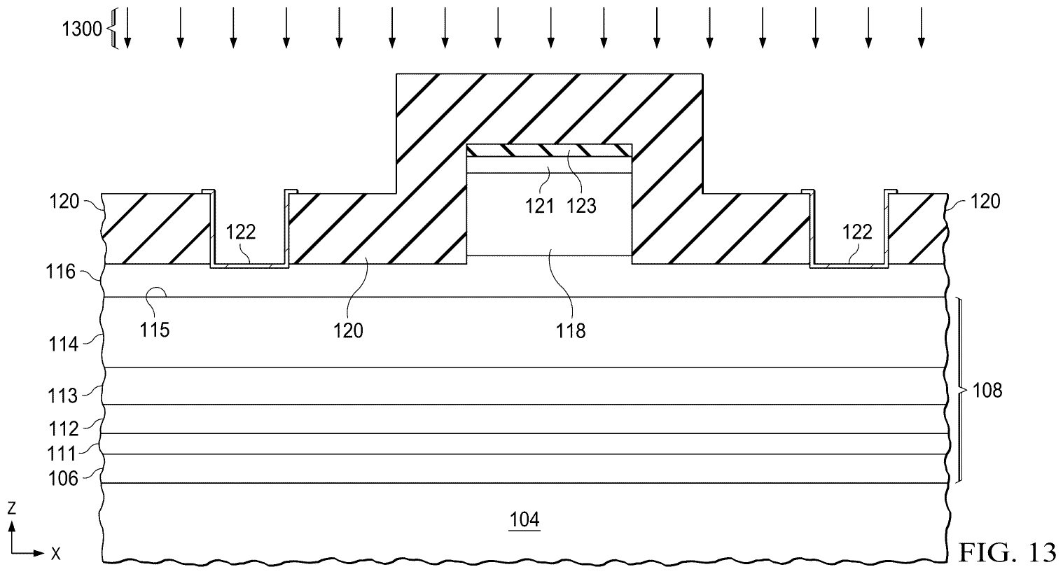

At 318 in FIG. 3, the method 300 includes forming an initial metal layer (metal 0 or M0). FIG. 13 shows one example, in which a metal deposition and etching process 1300 is performed that forms the conductive metal source/drain contacts 122 at least partially along sidewalls of the openings of the first silicon nitride layer 120, spaced apart from the p-GaN layer 118, and on respective etched portions of the aluminum gallium nitride barrier layer 116 in the openings (e.g., directly on and contacting or having one or more intervening layers or structures). In one example, the source/drain contacts 122 are or include one or more of titanium (Ti), aluminum, and/or copper, such as a titanium layer with a thickness of approximately 400 Å (0.04 μm), and a layer of aluminum copper (AlCu) with a thickness of approximately 1000 Å (0.1 μm) on the titanium layer. The drain contact 122 extends on a portion of the AlGaN barrier layer 116 in the drain opening of the first silicon nitride layer 120 and is spaced apart from the p-GaN layer 118. The process 1300 in one example can include one or more metal layer depositions followed by patterning, etching, and cleaning and optional annealing (e.g., at a temperature of approximately 800° C. for approximately 30 seconds).

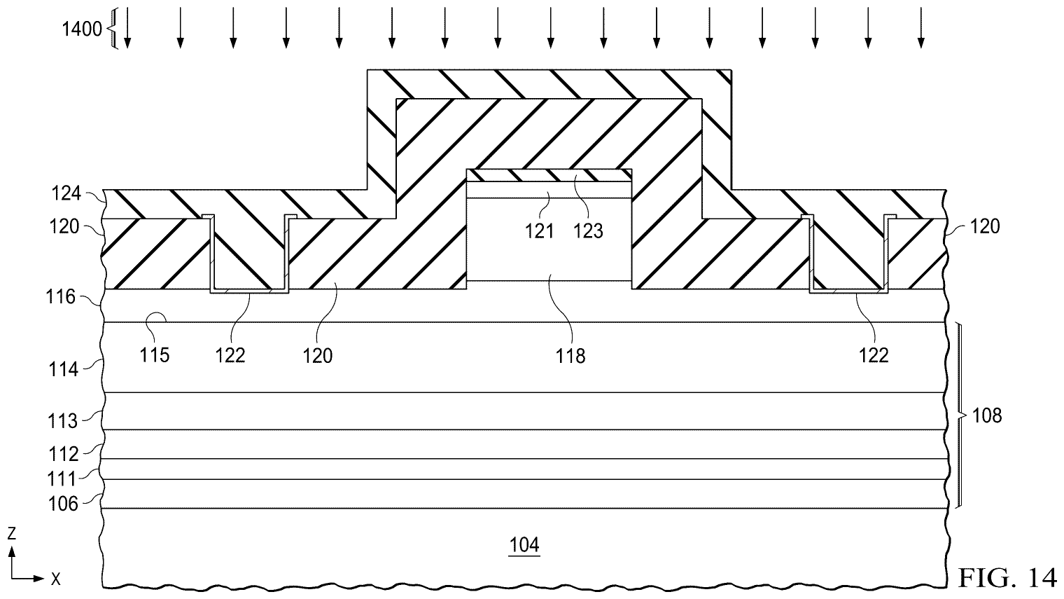

At 320 in FIG. 3, the method 300 includes forming another silicon nitride layer. FIG. 14 shows one example, in which a plasma enhanced CVD (PECVD) deposition process 1400 is performed that deposits the silicon nitride layer 124 (e.g., PSiN) to a thickness of approximately 820 Å (0.082 μm). The deposited silicon nitride layer 124 fills in the source and drain contact openings on the source and drain contacts 122 and extends over the silicon nitride layer 120 as shown in FIG. 14.

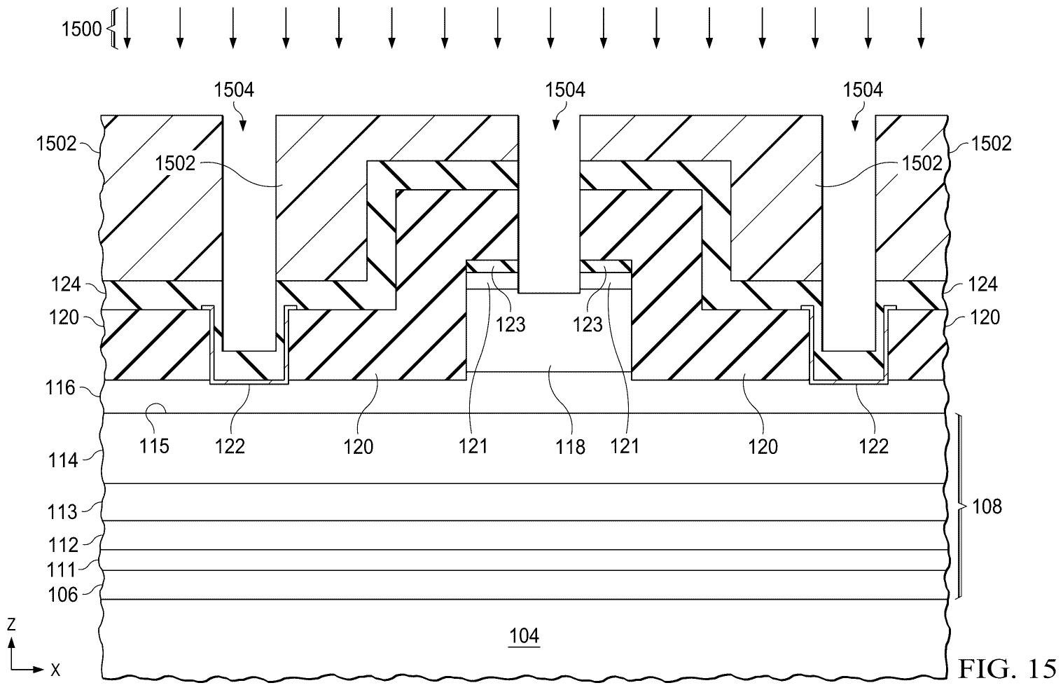

The method 300 continues in one example at 322 in FIG. 3 with concurrently etching a gate, source, and drain contact openings. FIG. 15 shows one example, in which an etch process 1500 is performed using an etch mask 1502 that forms openings 1504 for the gate, source, and drain. The etch process 1500 etches through portions of the silicon nitride layer 124 in the prospective source and drain areas, and etches through the silicon nitride layers 124, 120, and 123 as well as through the aluminum gallium nitride cap layer 121 and stops in the p-GaN layer 118 to form the opening 1504 for the gate contact. The etch process 1500 in one example etches through the AlGaN cap layer 121 and into a top side of the patterned p-GaN layer 118 and exposes a surface (e.g., an etched) surface of the patterned p-GaN layer 118. In another example, separate etch processes and associated masks can be used, for example, one etch process and mask to form the opening for the gate contact, and another etch process and mask to form the openings for the source and drain.

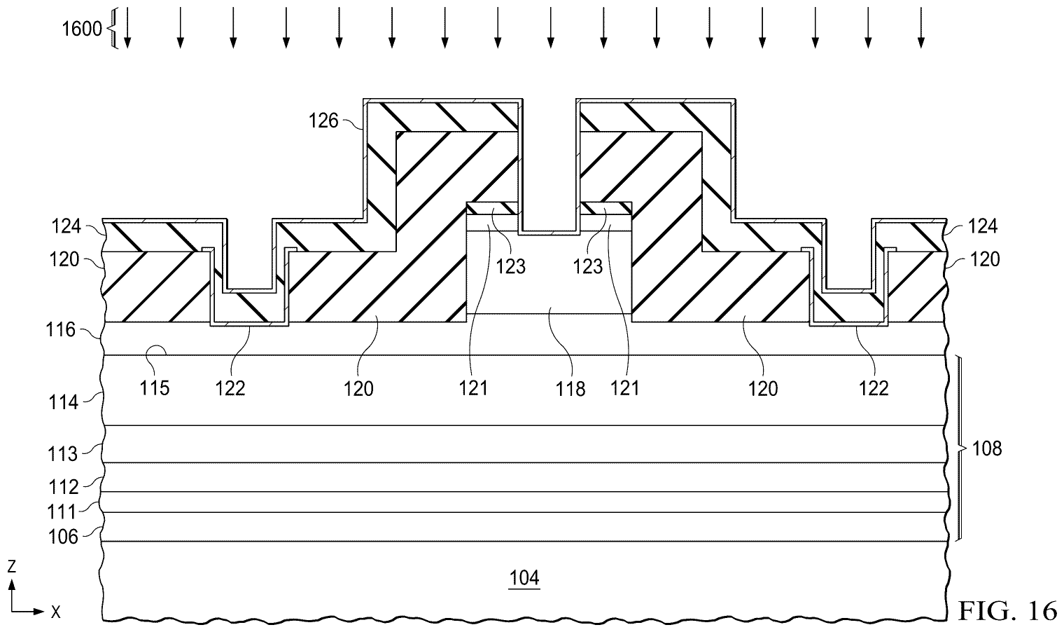

At 324 in FIG. 3, the method 300 includes forming the gate dielectric layer 126. FIG. 16 shows one example, in which a deposition process 1600 is performed that forms the dielectric layer 126 on the patterned p-GaN layer 118, for example, directly on a surface (e.g., etched surface) of the patterned p-GaN layer 118. The example process 1600 is a blanket deposition that forms the dielectric layer 126 on the silicon nitride layer 124 along the sidewalls and bottoms of the openings for the source, drain, and gate contacts and on the upper surfaces of the silicon nitride layer 124 as shown in FIG. 16. In one example, the process 1600 is or includes an atomic layer deposition (ALD) process that forms the dielectric layer 126 on the patterned p-GaN layer 118. The process 1600 in one example deposits one or more of Al₂O₃, SiO₂, HfO₂, ZrO₂, Ta₂O₅, TiO₂, La₂O₃, BaO, Sc₂O₃, Y₂O₃, Lu₂O₃, Nb₂O₅, AlN, ZrN, HfN, and Si₃N₄. In these or another example, the process 1600 deposits one or more of a composite film and a multilayer film stack. In these or another example, the process 1600 deposits one or more of a HfₓZr₁₋ₓO₂ composite film, an AlN/Al₂O₃ film stack, and an SiO₂/HfO₂ film stack. In these or another example, the process 1600 deposits the dielectric layer 126 to a thickness of approximately 20 Å or more and approximately 150 Å or less. In these or another example, the process 1600 deposits the dielectric layer 126 including a material with a bandgap greater than 5 eV. In these or another example, the process 1600 concurrently forms the dielectric layer 126 in the gate contact opening and in the source and drain contact openings.

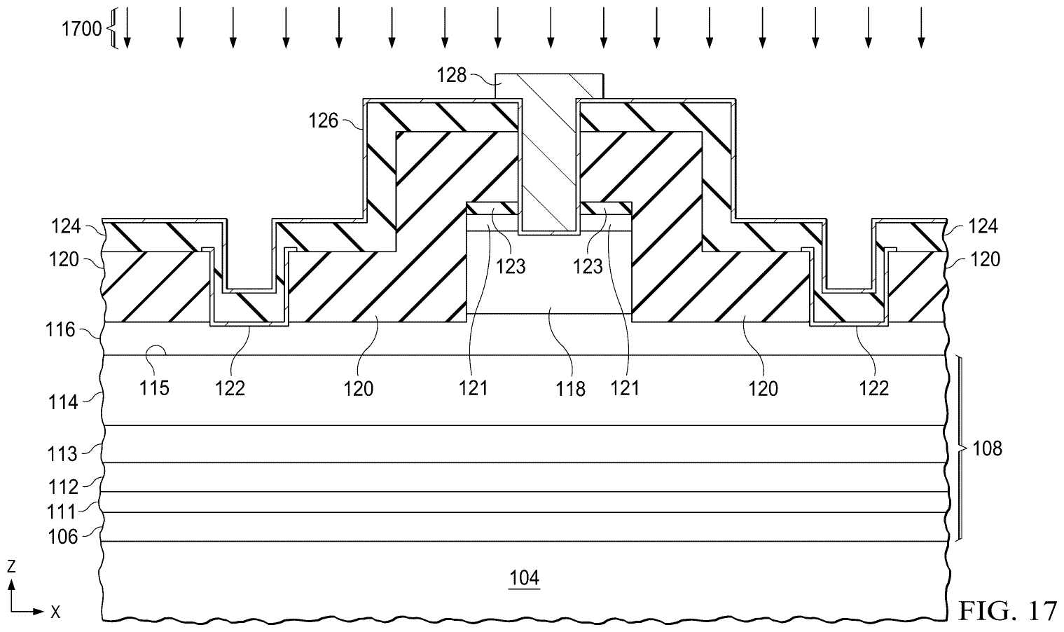

The method 300 continues at 326 in FIG. 3 with forming the gate electrode 128 on the dielectric layer 126. FIG. 17 shows one example, in which a conductive metal formation and patterning process 1700 is performed that forms the gate electrode 128 on the dielectric layer 126 on (e.g., directly on and contacting) the dielectric layer 126 along the bottom and sidewalls of the gate contact opening, and the patterned metal gate electrode 128 can extend on a portion of the top side of the dielectric layer 126 outside the opening. In one example, the process 1700 includes deposition of a suitable conductive metal (e.g., titanium tungsten, TiW, to a thickness of approximately 1800 Å (0.18 μm)), as well as photo mask deposition and patterning and gate metal etching to form the patterned gate electrode structure 128 as shown in FIG. 17.

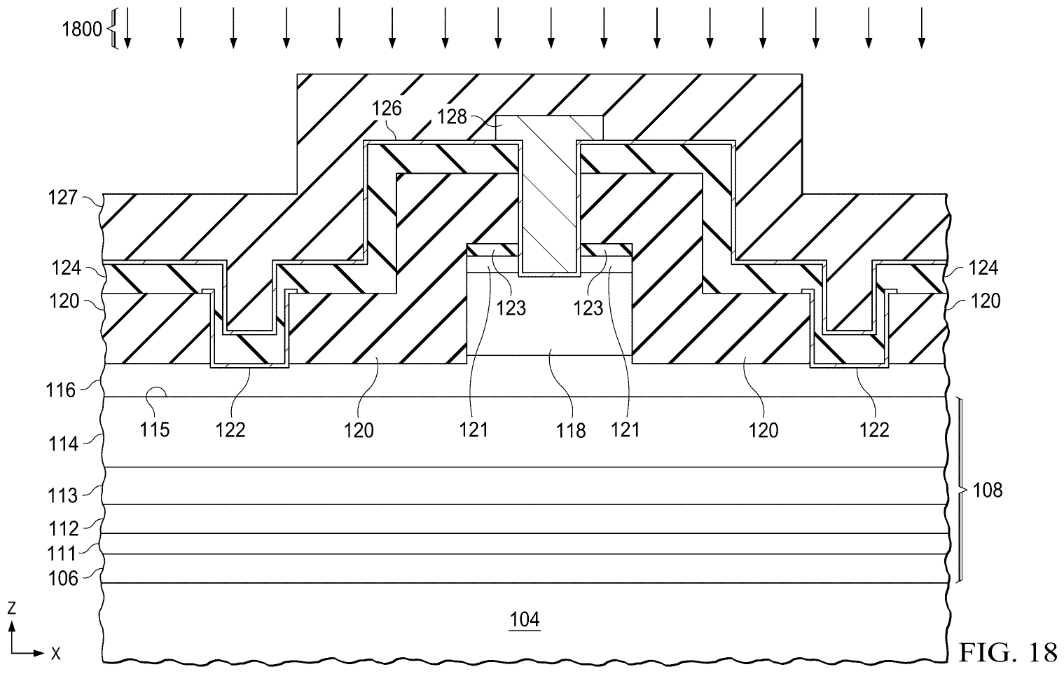

The method 300 continues at 327 in FIG. 3 with forming the silicon nitride layer 127. FIG. 18 shows one example, in which a PECVD deposition process 1800 is performed that deposits the silicon nitride layer 127 to a thickness of approximately 1700 Å (0.17 μm) on (e.g., directly on and contacting) the exposed portions of the patterned gate electrode 128 and the dielectric layer 126.

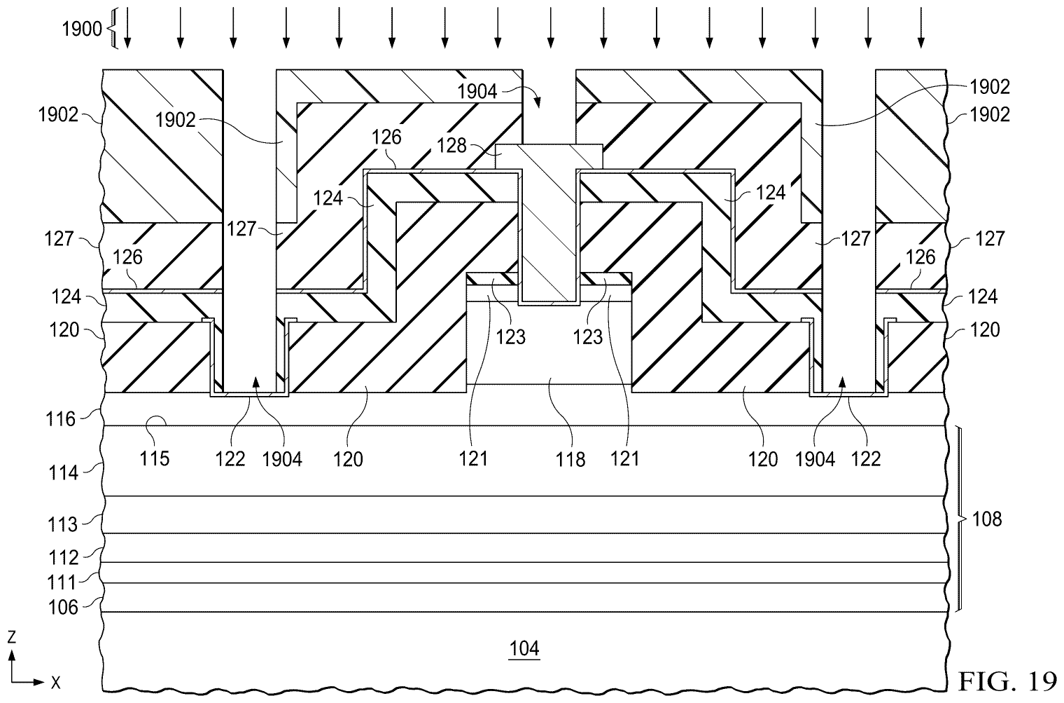

At 328 in FIG. 3, the method 300 continues with etching contact openings for a further metal layer or level (e.g., metal 1 or M1). FIG. 19 shows one example, in which an etch process 1900 is performed using an etch mask 1902 that forms openings 1904 for the source, drain, and gate. The etch process 1900 in one example etches through a portion of the silicon nitride layer 127 to form the opening 1904 for the further gate contact. The process 1900 also etches through portions of the silicon nitride layer 127, the dielectric layer 126 and the silicon nitride layer 124 in the prospective source and drain contact areas and exposes portions of the bottoms of the source and drain contacts 122.

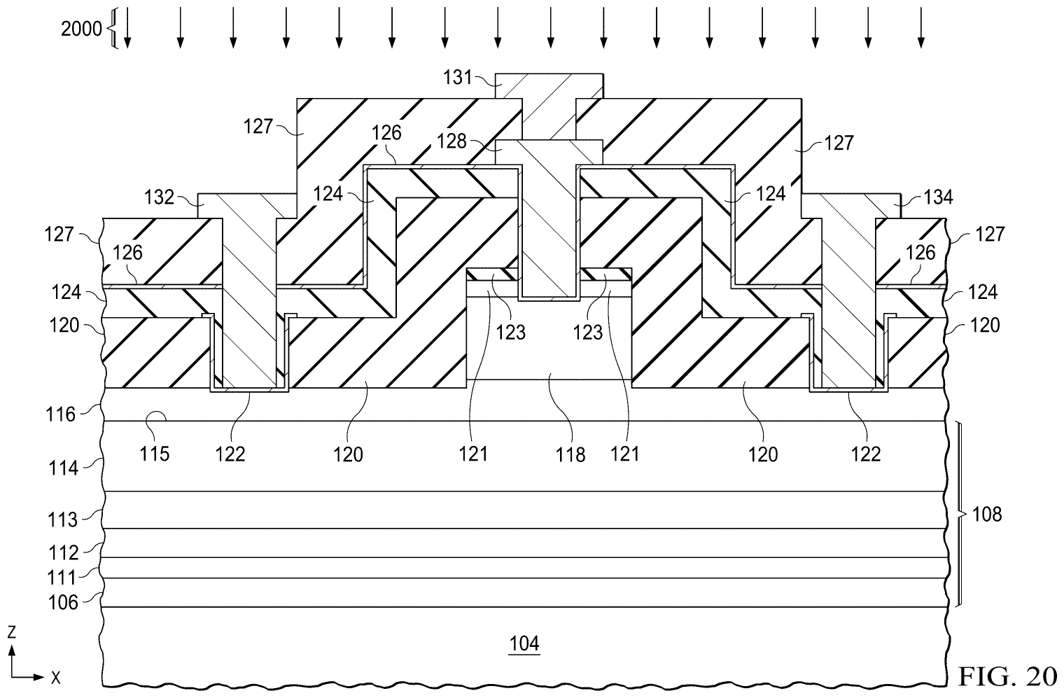

The method 300 continues at 330 in FIG. 3 with depositing and patterning conductive metal features of a further metal layer or level (e.g., metal 1 or M1). FIG. 20 shows one example, in which a process 2000 is performed that deposits conductive metal and patterns the deposited metal to form the further gate electrode 131 and the respective drain and source terminals 132 and 134. A bottom portion of the further gate electrode 131 extends in the gate contact opening at least partially on a top side of the gate electrode 128 (e.g., directly on and contacting or having one or more intervening layers or structures). The drain and source terminals 132 and 134 extend into the openings through the silicon nitride layers 124 and 127, and through the dielectric layer 126, and bottom sides of the terminals 132 and 134 extend on (e.g., directly on and contacting) bottom portions of the respective contacts 122. The further gate electrode 131 and the drain and source terminals 132 and 134 can be any conductive metal or combinations of conductive metals that are formed by deposition and suitable patterning processing 2000.

The method 300 in one example continues at 332 in FIG. 3 with further metallization and other backend processing, for example, to form a metallization structure (not shown) that electrically couples the transistor terminals D, G, and S to other components in a die area of a processed wafer and/or to bond pads or other top side terminals that allow electrical interconnection of the transistor to leads or other externally accessible connections of a finished semiconductor device 100.

The method 300 in one example also includes wafer testing at 334 in FIG. 3, as well as packaging at 336, for example, including singulating or separating individual die portions of a processed wafer, and packaging the individual dies using any suitable packaging structure, such as lead frames, molded structures, system on module packaging, chip on die packaging, substrates with conductive features, or combinations thereof to provide a finished semiconductor device, such as an integrated circuit semiconductor device 100 that includes the transistor 101, alone or along with other circuits (not shown). The method 300 in one example also includes final device testing at 338. FIG. 21 shows a perspective view of the finished packaged semiconductor device 100 having a molded package structure 2100 that encloses the semiconductor die and portions of the conductive leads 161-163 for electrical connection to the terminals of the example transistor 101.

The method 300 facilitates reduced transistor gate leakage through the device and improves the manufacturability of creating the p-GaN gate stack 102. Described examples etch away at least a portion of the AlGaN cap layer 121 from the top of the gate stack after the AlGaN cap layer 121 has protected the gate stack during intervening fabrication processing, and then deposit an atomic layer deposition (ALD) or another suitable gate dielectric layer 126. This approach avoids process variations (e.g., deposition and/or etching) of the AlGaN cap layer 121, and instead the aluminum gallium nitride cap layer 121 is partially removed during the gate contact etch processing (e.g., at 322 in FIG. 3). The example ALD or other suitable process used in forming the dielectric layer 126 (e.g., at 324) has good thickness control, for example, to atomic sub nanometer level, to facilitate deposition to the desired thickness independent of the wide variations associated with formation and etching of the aluminum gallium nitride cap layer 121. The use of ALD dielectric layer 126 in certain implementations also offers the ability to use dielectrics with increased bandgaps compared to the AlGaN cap layer 121 (e.g., such as Al₂O₃ or SiO₂, or other suitable materials described above), which will reduce the leakage through the structure. This represents an improvement in manufacturability and/or an improvement in performance. Moreover, leaving the aluminum gallium nitride cap layer 121 over the patterned gate stack until the p-GaN contact etching at 322 allows the AlGaN cap layer 121 to protect the p-GaN gate structure throughout the intervening processing steps of the method 300. In this manner, the existing AlGaN cap layer 121 can help to protect the gate structure during upstream processing, and the AlGaN cap layer 121 is then replaced with a superior dielectric layer 126 with precisely controlled thickness and with a larger bandgap for reduced leakage. This improves manufacturability and has the potential to improve device performance as well.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. A semiconductor device, comprising:
a dielectric layer on a first portion of a p-GaN layer;
a gate electrode on the dielectric layer; and
an AlGaN cap layer on a second portion of the p-GaN layer.

2. The semiconductor device of claim 1, wherein the dielectric layer includes one of Al₂O₃, SiO₂, HfO₂, ZrO₂, Ta₂O₅, TiO₂, La₂O₃, BaO, Sc₂O₃, Y₂O₃, Lu₂O₃, Nb₂O₅, AlN, ZrN, HfN, and Si₃N₄.

3. The semiconductor device of claim 1, wherein the dielectric layer includes one or more of a HfₓZr₁₋ₓO₂ composite film, an AlN/Al₂O₃ film stack, and an SiO₂/HfO₂ film stack.

4. The semiconductor device of claim 1, wherein the dielectric layer includes a material with a bandgap greater than 5 eV.

5. The semiconductor device of claim 1, wherein:
the p-GaN layer is on an AlGaN barrier layer;
the AlGaN barrier layer is on a GaN stack; and
the GaN stack is on a substrate.

6. The semiconductor device of claim 1, wherein the dielectric layer extends along a bottom of the gate electrode and along a portion of a lateral side of the gate electrode.

7. The semiconductor device of claim 1, wherein the AlGaN cap layer is laterally outward of a portion of the gate electrode.

8. The semiconductor device of claim 1, further comprising a silicon nitride layer on the AlGaN cap layer.

9. The semiconductor device of claim 1, wherein the p-GaN layer is on an AlGaN barrier layer, the semiconductor device further comprising:
a silicon nitride layer on the AlGaN barrier layer and extending on a side of the p-GaN layer and on a side of the AlGaN cap layer; and
another silicon nitride layer spaced apart from the AlGaN cap layer and extending on the silicon nitride layer in a drain access region between a gate stack and a drain contact.

10. A transistor, comprising:
a GaN stack on a substrate;
an AlGaN barrier layer on the GaN stack;
a gate stack including a p-GaN layer on the AlGaN barrier layer, a dielectric layer on a first portion of the p-GaN layer, and a gate electrode on the dielectric layer; and
an AlGaN cap layer on a second portion of the p-GaN layer and laterally outward of a portion of the gate electrode.

11. The transistor of claim 10, wherein the dielectric layer includes one of Al₂O₃, SiO₂, HfO₂, ZrO₂, Ta₂O₅, TiO₂, La₂O₃, BaO, Sc₂O₃, Y₂O₃, Lu₂O₃, Nb₂O₅, AlN, ZrN, HfN, and Si₃N₄.

12. The transistor of claim 10, wherein the dielectric layer has a thickness of approximately 20 Å or more and approximately 150 Å or less.

13. The transistor of claim 10, further comprising a silicon nitride layer on the AlGaN cap layer.

14. The transistor of claim 10, further comprising a silicon nitride layer on the AlGaN barrier layer and extending on a side of the p-GaN layer and on a side of the AlGaN cap layer.

15. The transistor of claim 10, wherein the dielectric layer continuously extends over a drain access region between the gate stack and a drain contact.

16. The transistor of claim 10, wherein the dielectric layer continuously extends from the gate stack to a drain contact, and the dielectric layer directly contacts the drain contact.

17. The transistor of claim 10, comprising a drain contact on a portion of the AlGaN barrier layer and spaced apart from the p-GaN layer.

18. The transistor of claim 10, comprising:
a first SiN layer extending on the AlGaN barrier layer and having an opening spaced apart from the p-GaN layer;
a drain contact on a portion of the AlGaN barrier layer and spaced apart from the p-GaN layer, the drain contact having a sidewall portion extending on a sidewall of the opening in the first SiN layer; and
a second SiN layer extending between the sidewall portion of the drain contact and a drain terminal.

19. A method of fabricating a semiconductor device, the method comprising:
forming a dielectric layer on a patterned p-GaN layer; and
forming a gate electrode on the dielectric layer.

20. The method of claim 19, wherein forming the dielectric layer includes depositing one of Al₂O₃, SiO₂, HfO₂, ZrO₂, Ta₂O₅, TiO₂, La₂O₃, BaO, Sc₂O₃, Y₂O₃, Lu₂O₃, Nb₂O₅, AlN, ZrN, HfN, and Si₃N₄ directly on a surface of the patterned p-GaN layer.

21. The method of claim 19, further comprising:
before patterning the p-GaN layer, forming an AlGaN cap layer on the p-GaN layer; and
after patterning the p-GaN layer, etching through the AlGaN cap layer to expose a surface of the patterned p-GaN layer.

22. The method of claim 19, wherein forming the dielectric layer includes performing an atomic layer deposition process to form the dielectric layer on the patterned p-GaN layer.

23. The method of claim 19, further comprising:
after patterning the p-GaN layer, forming a further dielectric layer on the patterned p-GaN layer; and
after forming the further dielectric layer, etching through the further dielectric layer and through an AlGaN cap layer to expose a surface of the patterned p-GaN layer.

24. The method of claim 19, further comprising:
after patterning the p-GaN layer, forming a source/drain opening through a SiN layer to expose a portion of an AlGaN barrier layer; and
after forming the source/drain opening, etching a trench into the patterned p-GaN layer to expose an etched surface of the patterned p-GaN layer.

25. The method of claim 19, further comprising concurrently etching a gate contact trench into the patterned p-GaN layer and a source/drain contact opening.

26. The method of claim 19, wherein forming the dielectric layer on the patterned p-GaN layer concurrently forms the dielectric layer in a source/drain contact opening.

27. The method of claim 19, comprising etching a source/drain contact opening through a portion of the dielectric layer.
